(19) United States
(12) Patent Application Publication
(10) Pub. No.: US 2020/0185628 A1
(43) Pub. Date: Jun. 11, 2020

(54) Device and method for manufacturing flexible substrate

(71) Applicant: BOE Technology Group Co., Ltd., Beijing (CN)

(72) Inventor: Congcong Jia, Beijing (CN)

(21) Appl. No.: 16/410,285

(22) Filed: May 13, 2019

(30) Foreign Application Priority Data
Dec. 6, 2018 (CN) 201822044948.3

(51) Int. Cl. H01L 51/00; H01L 51/52

(52) U.S. Cl. CPC H01L 51/0097; H01L 51/529; H01L 2251/5338; H01L 51/5253; H01L 51/003

(57) ABSTRACT

Embodiments of the present disclosure provide a flexible substrate, a display panel, a display device, and a method for manufacturing a flexible substrate. The flexible substrate includes: a functional layer for generating heat under an external action, which is thermally conductive; an electrically insulative and thermally insulative layer on a side of the functional layer; and an organic light emitting device on a side of the electrically insulative and thermally insulative layer facing away from the functional layer.

### CROSS-REFERENCE TO RELATED APPLICATION

This application claims priority of Chinese Patent Application No. 201822044948.3 filed on Dec. 6, 2018 in China National Intellectual Property Administration, the disclosure of which is incorporated herein by reference in entirety.

### TECHNICAL FIELD

Embodiments of the present disclosure relate to the field of display technology, and in particular, to a flexible substrate, a display panel, a display device, and a method for manufacturing a flexible substrate.

### BACKGROUND

OLEDS (i.e., organic light emitting diodes) have characteristics, such as self-illumination, clearness and brightness, lightness and thinness, fast response, wide viewing angle, low power consumption, large temperature range, low cost, simple manufacturing process and the like, therefore they have been applied to many mobile devices nowadays. Flexible OLEDS also have an advantage of being bendable and therefore have broader application prospect.

### SUMMARY

According to a first aspect of embodiments of the present disclosure, there is provided a flexible substrate, comprising:

a functional layer for generating heat under an external action, which is thermally conductive;

an electrically insulative and thermally insulative layer on a side of the functional layer; and

an organic light emitting device on a side of the electrically insulative and thermally insulative layer facing away from the functional layer.

According to some embodiments of the present disclosure, the functional layer is constructed as an electrically conductive and thermally conductive layer, and the electrically conductive and thermally conductive layer itself is capable of generating heat when the electrically conductive and thermally conductive layer is energized.

According to some embodiments of the present disclosure, the electrically conductive and thermally conductive layer is made of at least one of metal, conductive oxide or graphene.

According to some embodiments of the present disclosure, the electrically conductive and thermally conductive layer comprises at least one graphene layer and at least one metal layer which are alternately disposed, and a sub-layer of the electrically conductive and thermally conductive layer that is farthest from the electrically insulative and thermally insulative layer in all of sub-layers of the electrically conductive and thermally conductive layer is a graphene layer and a sub-layer of the electrically conductive and thermally conductive layer that is closest to the electrically insulative and thermally insulative layer in all of sub-layers of the electrically conductive and thermally conductive layer is a graphene layer.

According to some embodiments of the present disclosure, each of the at least one metal layer is a copper foil.

According to some embodiments of the present disclosure, each of the at least one metal layer comprises a plurality of metal wires arranged in parallel or a plurality of metal strips arranged in parallel.

According to some embodiments of the present disclosure, each of the at least one metal layer comprises one metal wire that is curvedly disposed between graphene layers.

According to some embodiments of the present disclosure, the electrically insulative and thermally insulative layer is made of a silicon oxide compound or a nitrogen silicon compound.

According to some embodiments of the present disclosure, the organic light emitting device comprises a flexible base substrate on the electrically insulative and thermally insulative layer and a pixel control circuit on a side of the flexible base substrate facing away from the electrically insulative and thermally insulative layer.

According to some embodiments of the present disclosure, the conductive oxide comprises one of copper oxide, iron oxide, zinc oxide, tin oxide, or titanium oxide.

According to a second aspect of embodiments of the present disclosure, there is provided a display panel, comprising the flexible substrate according to any one of the above embodiments.

According to a third aspect of embodiments of the present disclosure, there is provided a display device, comprising the display panel according to any one of the above embodiments.

According to a fourth aspect of embodiments of the present disclosure, there is provided a method for manufacturing a flexible substrate, the method comprising:

forming a functional layer on a rigid base substrate, the functional layer being configured for generating heat under an external action and being thermally conductive;

forming an electrically insulative and thermally insulative layer on the functional layer;

forming an organic light emitting device on the electrically insulative and thermally insulative layer; and

separating the functional layer from the rigid base substrate.

According to some embodiments of the present disclosure, the forming the functional layer on the rigid base substrate comprises:

forming a separation layer on the rigid base substrate; and

forming an electrically conductive and thermally conductive layer on the separation layer, wherein the electrically conductive and thermally conductive layer itself is capable of generating heat when the electrically conductive and thermally conductive layer is energized.

According to some embodiments of the present disclosure, the separating the functional layer from the rigid base substrate comprises:

energizing the electrically conductive and thermally conductive layer to soften or melt the separation layer; and

separating the electrically conductive and thermally conductive layer from the rigid base substrate.

According to some embodiments of the present disclosure, the separation layer is deformable by heat.

According to some embodiments of the present disclosure, the separation layer is made from one of polyimide, phosphorus, amine compound, polyalcohol compound, paraffin wax, or rosin.

According to some embodiments of the present disclosure, the rigid base substrate comprises one of a glass plate, an acrylic plate, or a metal plate.

According to some embodiments of the present disclosure, the electrically conductive and thermally conductive layer is made of at least one of metal, conductive oxide, or graphene.

According to some embodiments of the present disclosure, the electrically conductive and thermally conductive layer comprises at least one graphene layer and at least one metal layer which are alternately disposed, and a sub-layer of the electrically conductive and thermally conductive layer that is farthest from the electrically insulative and thermally insulative layer in all of sub-layers of the electrically conductive and thermally conductive layer is a graphene layer and a sub-layer of the electrically conductive and thermally conductive layer that is closest to the electrically insulative and thermally insulative layer in all of sub-layers of the electrically conductive and thermally conductive layer is a graphene layer.

### BRIEF DESCRIPTION OF THE DRAWINGS

In order to more clearly illustrate the technical solutions of the embodiments of the present disclosure, the accompanying drawings to be used in the description of the embodiments of the present disclosure will be briefly described below. It is apparent that the drawings in the following description only reflect some embodiments of the present disclosure, and other drawings may also be obtained by those skilled in the art based on these drawings without any creative efforts.

FIG. 1 is a schematic structural view of a flexible substrate according to some embodiments of the present disclosure;

FIG. 2 is a schematic top view of an electrically conductive and thermally conductive layer according to some embodiments of the present disclosure;

FIG. 3 is a schematic top view of another electrically conductive and thermally conductive layer according to some embodiments of the present disclosure; and

FIG. 4 is a schematic top view of a further electrically conductive and thermally conductive layer according to some embodiments of the present disclosure.

### DETAILED DESCRIPTION OF EMBODIMENTS

The technical solutions in the embodiments of the present disclosure will be clearly and completely described below with reference to the accompanying drawings in the embodiments of the present disclosure. It is apparent that the described embodiments represent a part of those in the present disclosure, but not all of the embodiments. All other embodiments obtained by those skilled in the art based on the embodiments of the present disclosure without any creative efforts fall within the scope of the present disclosure.

The current flexible OLED substrates without protective layers, is easily to be damaged for one side of the flexible substrate during preparation and use. In addition, in the manufacturing of a flexible OLED substrate, a flexible substrate is usually prepared on a rigid base substrate. After the device is manufactured, a mechanical stripping method or a laser stripping method is adopted to separate the flexible substrate from the rigid base substrate. The mechanical stripping method has simple processes, but it is easy to damage the flexible substrate, while the laser stripping method causes increased production costs due to high cost of the laser equipment.

Embodiments of the present disclosure provide a substrate to solve the problem that the flexible substrate is easily damaged and the problem presented in the process of striping of the flexible substrate and the rigid base substrate.

A flexible substrate, a display panel, and a display device provided by embodiments of the present disclosure will be described in detail below by several specific examples.

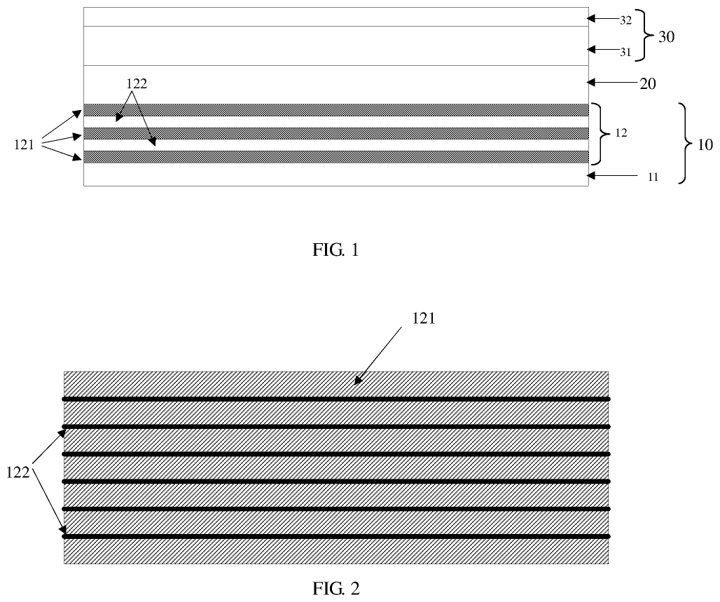

FIG. 1 is a schematic structural view of a flexible substrate according to an embodiment of the present disclosure. The flexible substrate includes:

a functional layer 10, the functional layer being electrically conductive and thermally conductive and capable of generating heat and deforming when energized;

an electrically insulative and thermally insulative layer 20 disposed on a side of the functional layer; and

an organic light emitting device 30 disposed on a side of the electrically insulative and thermally insulative layer facing away from the functional layer.

The functional layer 10 is electrically conductive and thermally conductive, and it generates heat and deforms when energized; the electrically insulative and thermally insulative layer 20 is disposed on one side of the functional layer 10; the organic light emitting device 30 is disposed on the side of the electrically insulative and thermally insulative layer 20 facing away from the functional layer 10.

In some embodiments of the present disclosure, the functional layer 10 generates heat when energized. Since the electrically insulative and thermally insulative layer 20 is provided between the functional layer 10 and the organic light emitting device 30, the heat generated by the functional layer 10 would not affect the organic light emitting device 30.

In some embodiments of the present disclosure, the flexible substrate is placed on the rigid base substrate during the preparation of the flexible substrate. The rigid base substrate includes one of a glass plate, an acrylic plate, or a metal plate. In some embodiments of the present disclosure, the rigid base substrate is a glass plate.

In some embodiments of the present disclosure, the organic light emitting device 30 includes a flexible base substrate 31 disposed on the electrically insulative and thermally insulative layer 20, and a pixel control circuit 32 disposed on a side of the flexible base substrate 31 facing away from the electrically insulative and thermally insulative layer 20.

In some embodiments of the present disclosure, the functional layer 10 includes a separation layer 11 and an electrically conductive and thermally conductive layer 12, and the separation layer 11 may be deformed by heat.

In some embodiments of the present disclosure, the separation layer 11 is disposed on the rigid base substrate during the preparation of the flexible substrate.

In some embodiments of the present disclosure, the separation layer 11 has a strong bonding force with the rigid base substrate at a normal temperature, and can be well bonded to the rigid base substrate. During the preparation of the organic light emitting device 30, no striping from the rigid base substrate occurs. Herein, the separation layer 11 can be softened or melted under a heating condition, and can be well separated from the rigid base substrate, so that the flexible substrate would not be damaged.

In some embodiments of the present disclosure, the separation layer 11 is made from one of polyimide, phosphorus, amine compound, polyalcohol compound, paraffin wax, or rosin.

In some embodiments of the present disclosure, the separated functional layer is located outside the flexible base substrate 31, and it forms a protective layer for the flexible substrate. Therefore, it improves water and oxygen resistance of the flexible substrate, protects the flexible substrate when the OLED screen is bent, and prevents the substrate from breaking when the screen is bent.

The electrically conductive and thermally conductive layer 12 is disposed between the separation layer 11 and the electrically insulative and thermally insulative layer 20, and the electrically conductive and thermally conductive layer 12 generates heat when energized.

The preparation process of the flexible substrate according to the present disclosure includes: forming a functional layer on a rigid base substrate, the functional layer including a separation layer and an electrically conductive and thermally conductive layer; preparing an electrically insulative and thermally insulative layer on the functional layer, and preparing a flexible base substrate on the electrically insulative and thermally insulative layer; manufacturing a pixel control circuit on the flexible base substrate; energizing the electrically conductive and thermally conductive layer in the functional layer to soften or melt the separation layer after a light emitting unit and an encapsulation layer are prepared on the pixel control circuit, so that the electrically conductive and thermally conductive layer is separated from the rigid base substrate and the electrically conductive and thermally conductive layer forms a protective layer for the flexible substrate. The electrically conductive and thermally conductive layer has good electrical conductivity, thermal conductivity and water and oxygen resistance, it can be separated from the rigid base substrate when energized, the functional layer is thin, and the substrate would not be bent due to the difference in thermal expansion coefficient.

In some embodiments of the present disclosure, a functional layer and an electrically insulative and thermally insulative layer are added between the rigid base substrate and the flexible substrate, and the functional layer includes a separation layer and an electrically conductive and thermally conductive layer. The electrically conductive and thermally conductive layer can generate heat when energized, to soften or melt the separation layer, so that the electrically conductive and thermally conductive layer is separated from the rigid base substrate instead of achieving the separation by laser irradiation, thereby avoiding damage to the flexible substrate caused by the mechanical separation. The separated electrically conductive and thermally conductive layer forms a protective layer for the flexible substrate. It improves water and oxygen resistance of the flexible substrate, protects the flexible substrate when the OLED screen is bent, and prevents the substrate from breaking when the screen is bent.

In some embodiments of the present disclosure, the electrically conductive and thermally conductive layer 12 is made of at least one of metal, conductive oxide, or graphene.

In some embodiments of the present disclosure, in the aspect of the material of the electrically conductive and thermally conductive layer, it requires that the heat of the electrically conductive and thermally conductive layer rises when energized, and the heat is easily dissipated. Herein, the conductive oxide includes copper oxide, iron oxide, zinc oxide, tin oxide, titanium oxide, or the like.

In some embodiments of the present disclosure, the graphene has excellent electrical conductivity and thermal conductivity, and its carrier mobility at room temperature is about 15000 cm²/(V·s), which is more than 10 times that of silicon material and more than twice that of indium antimonide (InSb), which has the highest carrier mobility at present. The pure defect-free single-layer graphene has a thermal conductivity of up to 5300 W/mK, and when it is used as a carrier, the thermal conductivity is also up to 600 W/mK. The graphene also has good toughness and can be bent, the theoretical Young's modulus of the graphene is up to 1.0 TPa, and the inherent tensile strength thereof is 130 GPa. The reduced graphene modified by hydrogen plasma or the like also has very good strength, and the average modulus thereof can be up to 0.25 TPa. In addition, the graphene also has good water and oxygen resistance.

In some embodiments of the present disclosure, referring to FIG. 1, the electrically conductive and thermally conductive layer 12 includes: graphene layers 121 and metal layers 122 which are alternately disposed; one of the graphene layers 121 is disposed on the separation layer 11, and another of the graphene layers 121 is disposed on a side of the electrically insulative and thermally insulative layer 20 facing away from the organic light emitting device 30.

In some embodiments of the present disclosure, the metal layers 122 are energized, and the temperature of the metal layers 122 increases after it is energized. Since the graphene layers 121 have good thermal conductivity, the heat generated by the metal layers can be quickly and uniformly conducted out, and transported to the separation layer 11 to increase the temperature of the separation layer 11. Herein, the contact of one of the graphene layers 121 to the electrically insulative and thermally insulative layer 20 can prevent the metal layers 122 from directly contacting the electrically insulative and thermally insulative layer 20.

In some embodiments of the present disclosure, a plurality of metal layers 122 are provided so as to increase the temperature of the electrically conductive and thermally conductive layer 12 as needed.

In some embodiments of the present disclosure, the metal layer 122 is a copper foil. The metal layer 122 includes a plurality of metal wires arranged in parallel or a plurality of metal strips arranged in parallel, or alternatively, the metal layer includes one metal wire that is curvedly disposed between the graphene layers.

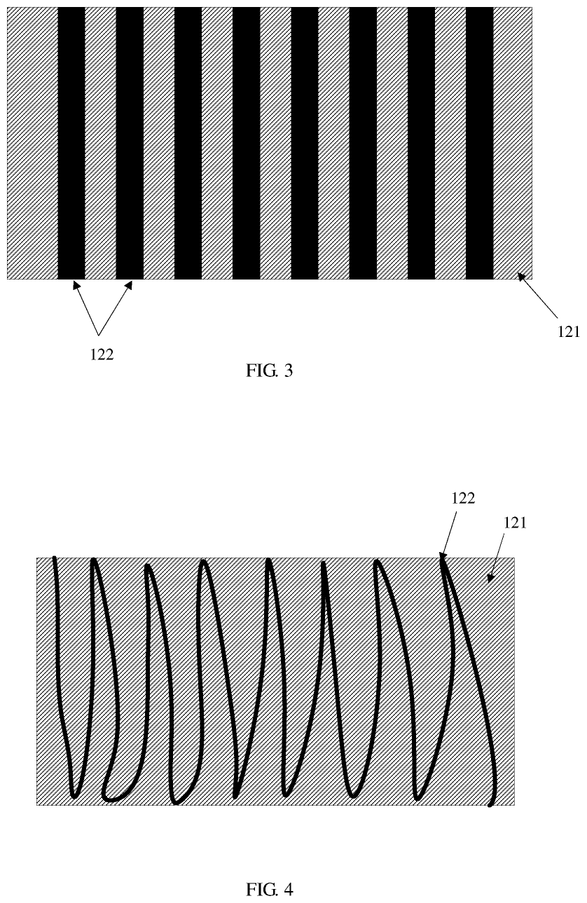

Referring to FIG. 2, FIG. 3 and FIG. 4, if one integral metal layer 122 is disposed on the graphene layer 121, the current will pass through the metal layer along one shortest line when the metal layer is energized, which cannot ensure that the entire metal plate is uniformly heated. Therefore, a plurality of metal wires, a plurality of metal strips or a curved metal may be uniformly disposed on the graphene layer 121 to form a metal layer. The graphene layer 121 can uniformly transfer heat to the separation layer 11.

In some embodiments of the present disclosure, the electrically insulative and thermally insulative layer 20 is made of a silicon oxide compound or a nitrogen silicon compound.

In some embodiments of the present disclosure, the electrically insulative and thermally insulative layer 20 can prevent the heat generated by the energization of the electrically conductive and thermally conductive layer from adversely affecting the organic light emitting device 30.

According to a second aspect of the embodiments of the present disclosure, there is provided a display panel including the flexible substrate according to any one of the above embodiments.

According to a third aspect of the embodiments of the present disclosure, there is provided a display device including the display panel described above.

According to a fourth aspect of the embodiments of the present disclosure, there is provided a method for manufacturing a flexible substrate, the method including:

forming a functional layer on a rigid base substrate, the functional layer being configured for generating heat under an external action and being thermally conductive;

forming an electrically insulative and thermally insulative layer on the functional layer;

forming an organic light emitting device on the electrically insulative and thermally insulative layer; and

separating the functional layer from the rigid base substrate.

In the embodiments of the present disclosure, the forming the functional layer on the rigid base substrate includes:

forming a separation layer on the rigid base substrate; and

forming an electrically conductive and thermally conductive layer on the separation layer,

wherein the electrically conductive and thermally conductive layer itself is capable of generating heat when the electrically conductive and thermally conductive layer is energized.

In some embodiments of the present disclosure, the separating the functional layer from the rigid base substrate includes:

energizing the electrically conductive and thermally conductive layer to soften or melt the separation layer; and

separating the electrically conductive and thermally conductive layer from the rigid base substrate.

In some embodiments of the present disclosure, the separation layer is deformable by heat.

In some embodiments of the present disclosure, the separation layer is made from one of polyimide, phosphorus, amine compound, polyalcohol compound, paraffin wax, or rosin.

In some embodiments of the present disclosure, the rigid base substrate includes one of a glass plate, an acrylic plate, or a metal plate.

In some embodiments of the present disclosure, the electrically conductive and thermally conductive layer is made of at least one of metal, conductive oxide, or graphene.

In some embodiments of the present disclosure, the electrically conductive and thermally conductive layer includes at least one graphene layer and at least one metal layer which are alternately disposed, and a sub-layer of the electrically conductive and thermally conductive layer that is farthest from the electrically insulative and thermally insulative layer in all of sub-layers of the electrically conductive and thermally conductive layer is a graphene layer and a sub-layer of the electrically conductive and thermally conductive layer that is closest to the electrically insulative and thermally insulative layer in all of sub-layers of the electrically conductive and thermally conductive layer is a graphene layer.

In summary, the flexible substrate provided by the embodiments of the present disclosure includes: a functional layer that is electrically conductive and thermally conductive and capable of generating heat and deforming when energized; an electrically insulative and thermally insulative layer disposed on a side of the functional layer; an organic light emitting device disposed on a side of the electrically insulative and thermally insulative layer facing away from the functional layer. In the embodiments of the present disclosure, an electrically insulative and thermally insulative layer is disposed on one side of the organic light emitting device to deliberately protect the organic light emitting device from being affected by heat, and a functional layer is disposed on one side of the electrically insulative and thermally insulative layer, to serve as a protective layer for the organic light emitting device.

It may be clearly understood by those skilled in the art that, for the sake of convenience and brevity of the description, the specific working processes of the system, the device and the unit described above can refer to the corresponding processes in the foregoing method embodiment, and therefore the details will not be described herein again.

The above description only refers to the optional embodiments of the present disclosure, but it is not intended to limit the present disclosure. Any modifications, equivalent substitutions and improvements made within the spirit and principle of the present disclosure should fall within the scope of the present disclosure.

The above description only refers to the specific embodiments of the present disclosure, but the scope of the present disclosure is not limited thereto. Any changes or substitutions that are easily obtained by those skilled in the art within the technical scope of the present disclosure should fall within the scope of the present disclosure. Therefore, the scope of the present disclosure should be defined by the appended claims.

What is claimed is:

1. A flexible substrate, comprising:
a functional layer for generating heat under an external action, which is thermally conductive;
an electrically insulative and thermally insulative layer on a side of the functional layer; and
an organic light emitting device on a side of the electrically insulative and thermally insulative layer facing away from the functional layer.

2. The flexible substrate according to claim 1, wherein the functional layer is constructed as an electrically conductive and thermally conductive layer, and the electrically conductive and thermally conductive layer itself is capable of generating heat when the electrically conductive and thermally conductive layer is energized.

3. The flexible substrate according to claim 2, wherein the electrically conductive and thermally conductive layer is made of at least one of metal, conductive oxide or graphene.

4. The flexible substrate according to claim 3, wherein the electrically conductive and thermally conductive layer comprises at least one graphene layer and at least one metal layer which are alternately disposed, and a sub-layer of the electrically conductive and thermally conductive layer that is farthest from the electrically insulative and thermally insulative layer in all of sub-layers of the electrically conductive and thermally conductive layer is a graphene layer and a sub-layer of the electrically conductive and thermally conductive layer that is closest to the electrically insulative and thermally insulative layer in all of sub-layers of the electrically conductive and thermally conductive layer is a graphene layer.

5. The flexible substrate according to claim 4, wherein each of the at least one metal layer is a copper foil.

6. The flexible substrate according to claim 4, wherein each of the at least one metal layer comprises a plurality of metal wires arranged in parallel or a plurality of metal strips arranged in parallel.

7. The flexible substrate according to claim 4, wherein each of the at least one metal layer comprises one metal wire that is curvedly disposed between graphene layers.

8. The flexible substrate according to claim 1, wherein the electrically insulative and thermally insulative layer is made of a silicon oxide compound or a nitrogen silicon compound.

9. The flexible substrate according to claim 1, wherein the organic light emitting device comprises a flexible base substrate on the electrically insulative and thermally insulative layer and a pixel control circuit on a side of the flexible base substrate facing away from the electrically insulative and thermally insulative layer.

10. The flexible substrate according to claim 3, wherein the conductive oxide comprises one of copper oxide, iron oxide, zinc oxide, tin oxide, or titanium oxide.

11. A display panel, comprising the flexible substrate according to claim 1.

12. A display device, comprising the display panel according to claim 11.

13. A method for manufacturing a flexible substrate, the method comprising:
forming a functional layer on a rigid base substrate, the functional layer being configured for generating heat under an external action and being thermally conductive;
forming an electrically insulative and thermally insulative layer on the functional layer;
forming an organic light emitting device on the electrically insulative and thermally insulative layer; and
separating the functional layer from the rigid base substrate.

14. The method according to claim 13, wherein the forming the functional layer on the rigid base substrate comprises:
forming a separation layer on the rigid base substrate; and
forming an electrically conductive and thermally conductive layer on the separation layer,
wherein the electrically conductive and thermally conductive layer itself is capable of generating heat when the electrically conductive and thermally conductive layer is energized.

15. The method according to claim 14, wherein the separating the functional layer from the rigid base substrate comprises:
energizing the electrically conductive and thermally conductive layer to soften or melt the separation layer; and
separating the electrically conductive and thermally conductive layer from the rigid base substrate.

16. The method according to claim 14, wherein the separation layer is deformable by heat.

17. The method according to claim 16, wherein the separation layer is made from one of polyimide, phosphorus, amine compound, polyalcohol compound, paraffin wax, or rosin.

18. The method according to claim 13, wherein the rigid base substrate comprises one of a glass plate, an acrylic plate, or a metal plate.

19. The method according to claim 14, wherein the electrically conductive and thermally conductive layer is made of at least one of metal, conductive oxide, or graphene.

20. The method according to claim 19, wherein the electrically conductive and thermally conductive layer comprises at least one graphene layer and at least one metal layer which are alternately disposed, and a sub-layer of the electrically conductive and thermally conductive layer that is farthest from the electrically insulative and thermally insulative layer in all of sub-layers of the electrically conductive and thermally conductive layer is a graphene layer and a sub-layer of the electrically conductive and thermally conductive layer that is closest to the electrically insulative and thermally insulative layer in all of sub-layers of the electrically conductive and thermally conductive layer is a graphene layer.
